(19) United States
(12) Patent Application Publication
(10) Pub. No.: US 2021/0125910 A1
(43) Pub. Date: Apr. 29, 2021

(54) SEMICONDUCTOR STRUCTURE

(71) Applicant: NANYA TECHNOLOGY CORPORATION, New Taipei city (TW)

(72) Inventors: Shing-Yih SHIH, New Taipei City (TW); Tse-Yao HUANG, Taipei City (TW)

(21) Appl. No.: 16/663,369

(22) Filed: Oct. 25, 2019

(51) Int. Cl. H01L 23/498; H01L 23/00

(52) U.S. Cl. CPC H01L 23/49822; H01L 23/49838; H01L 2224/29; H01L 24/29; H01L 23/49861

(57) ABSTRACT

A semiconductor structure includes a first component and a second component bonded thereof. The first component includes a first interlayer dielectric (ILD) layer, a first interconnect structure, a first seal ring, and a first bonding layer. The first interconnect structure is in the first ILD layer and surrounded by the first seal ring. The first bonding layer covers the first ILD layer and the first interconnect structure, and has a portion surrounds the first seal ring. The second component includes a second ILD layer, a second interconnect structure, a second seal ring, and a second bonding layer. The second interconnect structure is in the second ILD layer and surrounded by the second seal ring. The second bonding layer is in contact with the first bonding layer and covers the second ILD layer and the second interconnect structure, and has a portion surrounds the second seal ring.

### BACKGROUND

### Field of Invention

The present invention relates to a semiconductor structure.

### Description of Related Art

In recent years, the vertical integration of two-dimensional (2D) integrated circuits (ICs) into three-dimensional (3D) ICs has emerged as a potential approach to improving processing capabilities and power consumption of ICs. Wafer-to-wafer bonding technology has been developed to bond two wafers together, such that the 2D ICs in the respective wafers can be integrated into 3D ICs.

### SUMMARY

In accordance with an aspect of the present invention, a semiconductor structure is provided. The semiconductor structure includes a first component and a second component bonded to the first component. The first component includes a first interlayer dielectric layer, a first interconnect structure, a first seal ring, a first trench, and a first bonding layer. The first interconnect structure is in the first interlayer dielectric layer, wherein the first interconnect structure has a first surface exposed by the first interlayer dielectric layer. The first seal ring surrounds the first interconnect structure. The first trench is in the first interlayer dielectric layer and surrounding the first seal ring. The first bonding layer covers the first interlayer dielectric layer and the first surface of the first interconnect structure. The second component includes a second interlayer dielectric layer, a second interconnect structure, a second seal ring, a second trench, and a second bonding layer. The second interconnect structure is in the second interlayer dielectric layer, wherein the second interconnect structure has a second surface exposed by the second interlayer dielectric layer. The second seal ring surrounds the second interconnect structure. The second trench is in the second interlayer dielectric layer and surrounds the second seal ring. The second bonding layer covers the second interlayer dielectric layer and the second surface of the second interconnect structure, wherein the second bonding layer is in contact with the first bonding layer.

According to some embodiments of the present invention, the first trench and the second trench are respectively recessed from a top surface of the first interlayer dielectric layer and a bottom surface of the second interlayer dielectric layer, wherein the top surface is level with the first surface of the first interconnect structure, and the bottom surface is level with the second surface of the second interconnect structure.

According to some embodiments of the present invention, the first trench and the second trench respectively have a shape independently selected from a group consisting of a circular shape, a square shape, and a polygon shape viewed from top.

According to some embodiments of the present invention, the first trench is aligned with the second trench.

According to some embodiments of the present invention, the semiconductor structure further includes a third trench in the first interlayer dielectric layer and between the first seal ring and the first interconnect structure, wherein the first bonding layer extends into the third trench; and a fourth trench in the second interlayer dielectric layer and between the second seal ring and the second interconnect structure, wherein the second bonding layer extends into the fourth trench.

According to some embodiments of the present invention, the first bonding layer includes a first guard ring portion in the first trench and a first plane portion on the first guard ring portion, and the second bonding layer includes a second guard ring portion in the second trench and a second plane portion under the second guard ring portion.

According to some embodiments of the present invention, the first guard ring portion and the second guard ring portion respectively include a plurality of separate segments around the first seal ring and the second seal ring.

According to some embodiments of the present invention, the first bonding layer and the second bonding layer includes organic material.

According to some embodiments of the present invention, the semiconductor structure further includes a first conductor penetrating the second interlayer dielectric layer, the second bonding layer, and the first bonding layer to connect to the first interconnect structure; and a second conductor penetrating the second interlayer dielectric layer to connect to the second interconnect structure.

According to some embodiments of the present invention, the semiconductor structure further includes a first substrate under the first interlayer dielectric layer and a second substrate on the second interlayer dielectric layer.

It is to be understood that both the foregoing general description and the following detailed description are by examples, and are intended to provide further explanation of the invention as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of various intermediary stages in the manufacturing of semiconductor structure in accordance with some embodiments of this invention.

FIG. 2 is a cross-sectional view of various intermediary stages in the manufacturing of semiconductor structure in accordance with some embodiments of this invention.

FIG. 3 is a cross-sectional view of various intermediary stages in the manufacturing of semiconductor structure in accordance with some embodiments of this invention.

FIG. 4 is a top view of various intermediary stages in the manufacturing of semiconductor structure in accordance with some embodiments of this invention.

FIG. 5 is a top view of various intermediary stages in the manufacturing of semiconductor structure in accordance with some embodiments of this invention.

FIG. 6 is a top view of various intermediary stages in the manufacturing of semiconductor structure in accordance with some embodiments of this invention.

FIG. 7 is a cross-sectional view of various intermediary stages in the manufacturing of semiconductor structure in accordance with some embodiments of this invention.

FIG. 8 is a cross-sectional view of various intermediary stages in the manufacturing of semiconductor structure in accordance with some embodiments of this invention.

FIG. 9 is a cross-sectional view of various intermediary stages in the manufacturing of semiconductor structure in accordance with some embodiments of this invention.

### DETAILED DESCRIPTION

In order to make the description of the present disclosure more detailed and complete, the following illustratively describes implementation aspects and specific embodiments of the present disclosure; however, this is not the only form in which the specific embodiments of the present disclosure are implemented or utilized. The embodiments disclosed below may be combined with or substituted by each other in an advantageous manner, and other embodiments may be added to an embodiment without further recording or description. In the following description, numerous specific details will be described in detail to enable readers to fully understand the following embodiments. However, the embodiments of the present disclosure may be practiced without these specific details.

Specific embodiments of the components and arrangements described below are intended to simplify the present disclosure. Of course, these are merely embodiments and are not intended to limit the present disclosure. For example, forming a first feature above or on a second feature in the subsequent description may include an embodiment in which the first feature and the second feature are formed as in direct contact, or include an embodiment in which an additional feature is formed between the first feature and the second feature such that the first feature and the second feature are not in direct contact. Additionally, component symbols and/or letters may be repeated in various embodiments of the present disclosure. This repetition is for the purpose of simplicity and clarity, and does not in itself indicate the relationship between the various embodiments and/or configurations discussed.

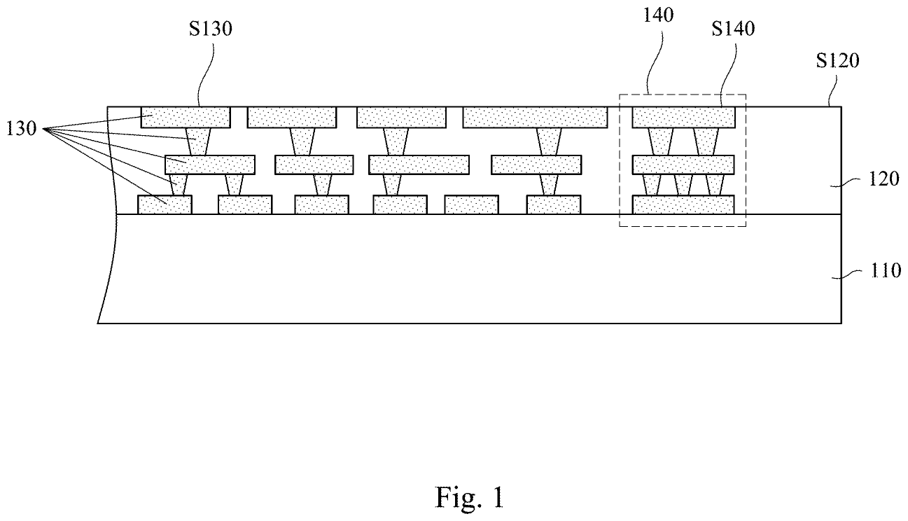

FIGS. 1-3 and FIGS. 7-9 are cross-sectional views of various intermediary stages in the manufacturing of a semiconductor structure 300 in accordance with some embodiments of this disclosure.

Please refer to FIG. 1, a precursor structure is provided. The precursor structure may include a first substrate 110, a first interlayer dielectric (ILD) layer 120, a first interconnect structure 130, and a first seal ring 140. As shown in FIG. 1, the first ILD layer 120 is formed on the first substrate 110. In some embodiments, the first substrate 110 may be semiconductor substrate, such as a silicon substrate, a silicon germanium substrate, a silicon carbon substrate, an III-V compound semiconductor substrate, or the like. In some embodiments, the first substrate 110 may include one or more active and/or passive device (not shown) such as transistor, capacitance. In some embodiments, the first interlayer dielectric layer 120 includes silicon dioxide, a low k dielectric, some other dielectric, or a combination thereof.

One or more first interconnect structures 130 is disposed in the first interlayer dielectric layer 120, and the first interconnect structure 130 has a first surface S130 exposed by the first interlayer dielectric layer 120. In some embodiments, the first interconnect structures 130 may include conductive line, conductive via hole, conductive pad, conductive contact, or the like, but is not limited thereto. In some embodiments, the first interconnect structure 130 includes conductive material, for example, aluminum copper, copper, aluminum, tungsten, some other metal or conductive material, or a combination of thereof.

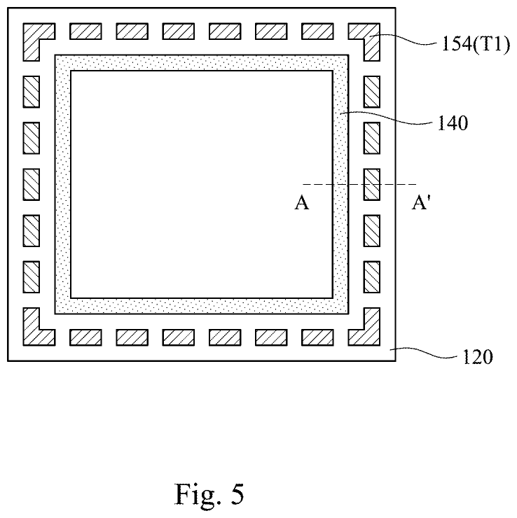

The first seal ring 140 is disposed in the first ILD layer 120 and surrounds the first interconnect structure 130. As shown in FIG. 1, the first seal ring 140 (the dashed structure shown in FIG. 1) may be disposed on an edge of the first ILD layer 120. Specifically, the first seal ring 140 may surround the first interconnect structure 130 in a top view (shown in FIG. 5). It is noted that the structure of the first seal ring 140 is not limited in the structure shown in FIG. 1, the first seal ring 140 may be any conventional seal ring structure that functions as a crack stop structure. In some embodiments, the first seal ring 140 includes conductive material, for example, aluminum copper, copper, aluminum, tungsten, some other metal or conductive material, or a combination of thereof. In some embodiments, a top surface S140 of the first seal ring 140 is level with a top surface S120 of the first ILD layer 120 and the first surface S130 of the first interconnect structure 130.

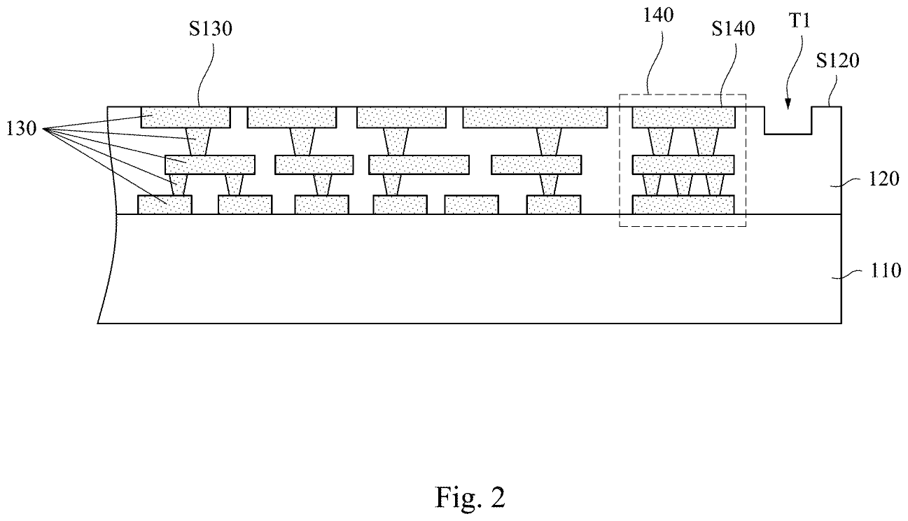

Please refer to FIG. 2, a first trench T1 is formed in the first ILD layer 120. As shown in FIG. 2, the first trench T1 is recessed from the top surface S120 of the first interlayer dielectric layer 120. The first trench T1 may be disposed on the edge of the first ILD layer 120. Specifically, the first trench T1 can be disposed between the edge of the first ILD layer 120 and the first seal ring 140 to encircle the first seal ring 140 and the first interconnect structure 130. It is noted that a shape of the first trench T1 is not limited to FIG. 2. That is, a dimension (e.g., width, length, or depth) of the first trench T1 may be selected depending on the needed.

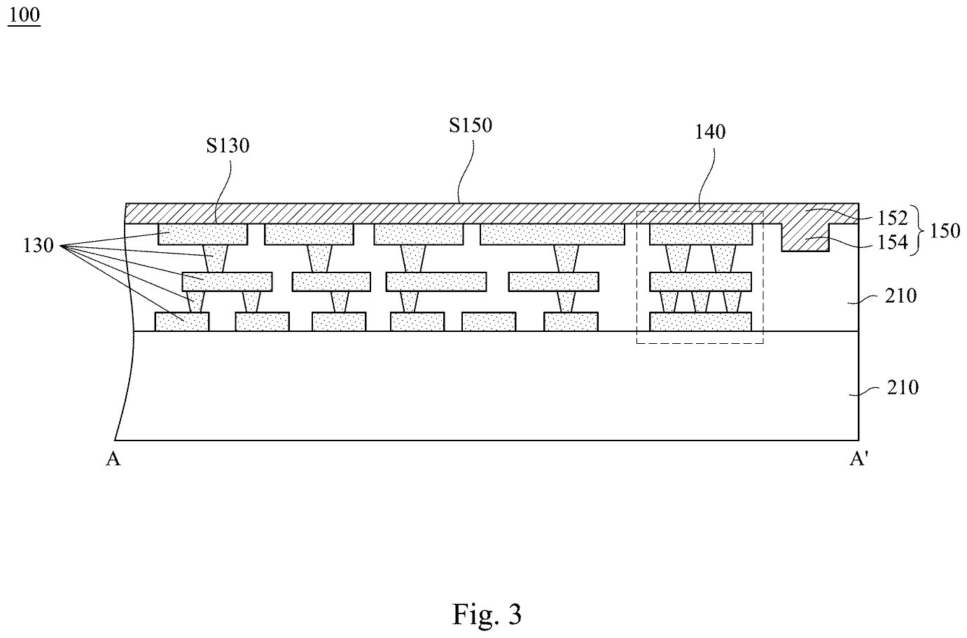

Please refer to FIG. 3, a first bonding layer 150 is formed on the first ILD layer 120. As shown in FIG. 3, the first bonding layer 150 covers the first interlayer dielectric layer 120, the first interconnect structure 130, and the first seal ring 140. Specifically, the first bonding layer 150 is filled in the trench T1 by suitable coating method. More specifically, the first bonding layer 150 includes a first guard ring portion 154 in the first trench T1 and a first plane portion 152 on the first guard ring portion 154. The first plane portion 152 covering the first ILD layer 120 has a substantially flat top surface S150. In some embodiments, the first bonding layer 150 includes organic material. In some examples, the first bonding layer 150 may be Benzocyclobutene (BCB), Polybenzoxazoles (PBO), but is not limited thereto. In some embodiments, the material of the first bonding layer 150 is different from the first ILD layer 120. As shown in FIG. 3, a first component 100 is thus formed.

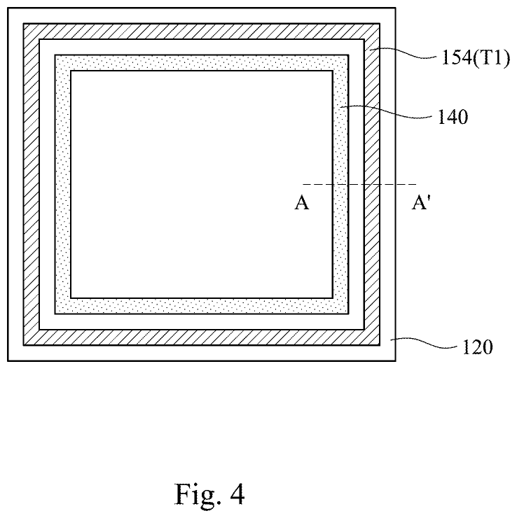

FIG. 4 is a top view of the first component 100 shown in FIG. 3 in accordance with some embodiments of the present disclosure. Specifically, FIG. 3 is a cross-section view taken along line A-A′ of FIG. 4 according to some embodiments of the present disclosure. It is noted that the first plane portion 152 of the first bonding layer 150 and the first interconnect structure 130 are not shown in FIG. 4 for simplifying the drawing. As shown in FIG. 4, the first guard ring portion 154 of the first bonding layer 150 surrounds the first seal ring 140. In some embodiments, the first trench T1 has a shape independently selected from a group consisting of a circular shape, a square shape, and a polygon shape viewed from top. In some examples, the first trench T1 has a continuous square shape in the top view, as illustrated in FIG. 4.

FIG. 5 is a top view of the first component 100 shown in FIG. 3 in accordance with other embodiments of the present disclosure. Specifically, FIG. 3 is a cross-section view taken along line A-A′ of FIG. 5 according to other embodiments of the present disclosure. The first plane portion 152 of the first bonding layer 150 and the first interconnect structure 130 are also not shown in FIG. 5 for simplifying the drawing. As shown in FIG. 5, the first guard ring portion 154 includes a plurality of separate segments around the first seal ring 140. Specifically, the first guard ring portion 154 may have a discontinuous shape surrounds the first seal ring 140 view from top.

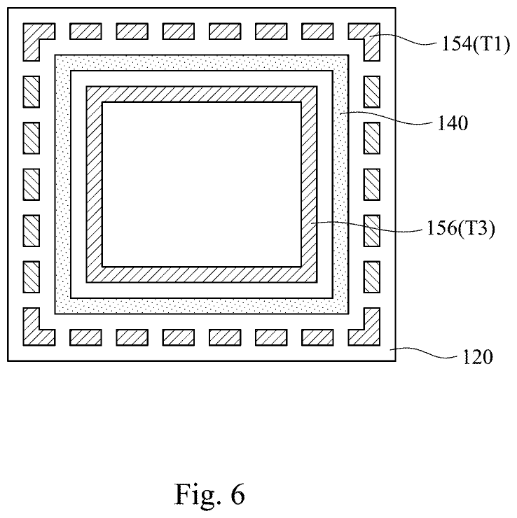

In some embodiments, a third trench T3 is further formed in the first interlayer dielectric layer 120. As shown in FIG. 6, the third trench T3 is encircled by the first seal ring 140. Specifically, the third trench may be disposed between the first seal ring 140 and the first interconnect structure 130 (shown in FIG. 3). More specifically, the first bonding layer 150 may be extended into the third trench T3 to form an inner first guard ring portion 156. In some embodiments, the third trench T3 (i.e., the inner first guard ring portion 156) has a shape independently selected from a group consisting of a circular shape, a square shape, and a polygon shape viewed from top. In some examples, the third trench T3 and the inner first guard ring portion 156 have a continuous square shape in the top view as shown in FIG. 6. In other examples, the inner first guard ring portion 156 has a discontinuous shape surrounds the first seal ring 140 view from top. Specifically, the inner first guard ring portion 156 may include a plurality of separate segments.

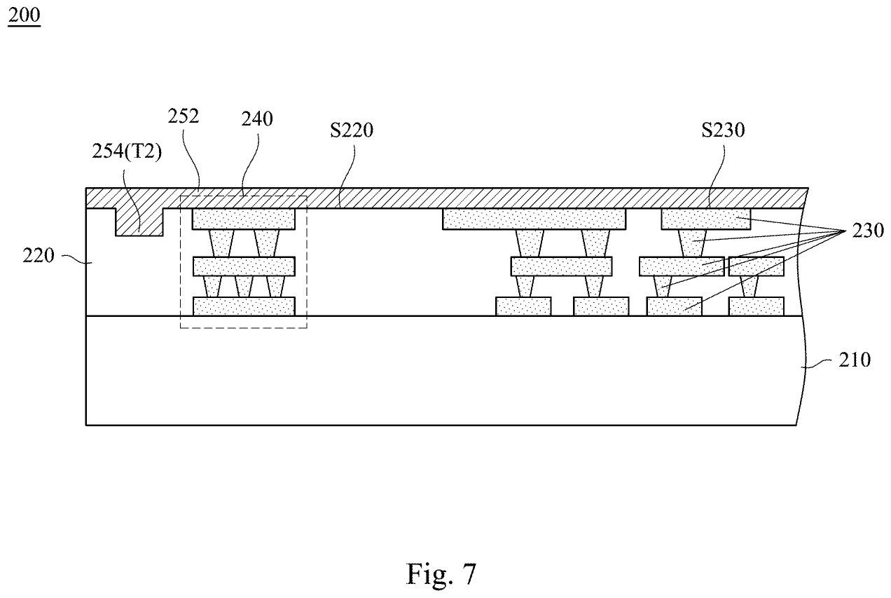

FIG. 7 illustrates a cross-sectional view of a second component 200 in accordance with some embodiments of the present disclosure. The second component 200 includes a second substrate 210, a second interlayer dielectric (ILD) layer 220, a second interconnect structure 230, a second seal ring 240, a second trench T2, and a second bonding layer 250. The materials and the manufacturing methods of the elements in the second component 200 may be the same as the elements having similar reference numbers of the aforementioned first component 100 shown in FIG. 3, and will not be repeated hereinafter.

As shown in FIG. 7, the second ILD layer 220 is disposed on the second substrate 210 and has a top surface S220. One or more second interconnect structure 230 is disposed in the second ILD layer 220 and has a second surface S230 exposed by the second ILD layer 220. In some embodiments, the second interconnect structure 230 may include conductive line, conductive via hole, conductive pad, conductive contact, or the like, but is not limited thereto. The arrangement of the plurality of second interconnect structures 230 may be different to the first interconnect structures 130 shown in FIG. 3.

The second seal ring 240 (the dashed structure shown in FIG. 7) is disposed in the second ILD layer 220 and surrounds the second interconnect structure 230. In some embodiments, a top surface S240 of the second seal ring 240 is level with a top surface S220 of the second ILD layer 220 and the second surface S230 of the second interconnect structure 230. The second seal ring 240 may be any conventional seal ring structure that functions as a crack stop structure.

The second trench T2 is formed in the second ILD layer 220. The second trench T2 is recessed from the second surface S220 of the second ILD layer 220. In some embodiments, the second trench T2 is disposed on an edge of the second ILD layer 220 and surrounds the second seal ring 240. Specifically, the second trench T2 can be disposed between the edge of the second ILD layer 220 and the second seal ring 240 to encircle the second seal ring 240 and the second interconnect structure 230. It is noted that a shape of the second trench T2 is not limited to FIG. 7. That is, a dimension (e.g., width, length, or depth) of the second trench T2 may be selected depending on the needed.

The second bonding layer 250 is formed on the second ILD layer 220. As shown in FIG. 7, the second bonding layer 250 covers the second interlayer dielectric layer 220, the second interconnect structure 230, and the second seal ring 240. Specifically, the second bonding layer 250 includes a second guard ring portion 254 in the second trench T2 and a second plane portion 252 on the second guard ring portion 254. The second plane portion 252 covering the second ILD layer 220 has a substantially flat top surface S250.

In some embodiments, the second guard ring portion 254 of the second bonding layer 250 surrounds the second seal ring 240. In some embodiments, the second trench T2 has a shape independently selected from a group consisting of a circular shape, a square shape, and a polygon shape viewed from top. In some examples, the second trench T2 has a continuous square shape same as the first trench T2 illustrated in FIG. 4 in the top view. In other examples, the second guard ring portion 254 includes a plurality of separate segments (not shown) around the second seal ring 240. Specifically, the second guard ring portion 254 may have a discontinuous shape surrounds the second seal ring 240 similar to the first guard ring portion 154 shown in FIG. 5 view from top.

In some embodiments, a fourth trench (not shown) is further formed in the second interlayer dielectric layer 220. The fourth trench may be similar to the third trench T3 shown in FIG. 6. The fourth trench may be encircled by the second seal ring 240. Specifically, the fourth trench may be disposed between the second seal ring 240 and the second interconnect structure 230. More specifically, the second bonding layer 250 may be extended into the fourth trench to form an inner second guard ring portion (not shown) similar to the inner first guard ring portion 156 shown in FIG. 6. In some embodiments, the fourth trench (i.e., the inner second guard ring portion) has a shape independently selected from a group consisting of a circular shape, a square shape, and a polygon shape viewed from top. In some examples, the fourth trench and the inner second guard ring portion have a continuous square shape in the top view similar to the third trench T3 and the inner first guard ring portion 156 shown in FIG. 6. In other examples, the inner second guard ring portion may have a discontinuous shape surrounds the second seal ring 240 view from top. Specifically, the inner second guard ring portion may include a plurality of separate segments.

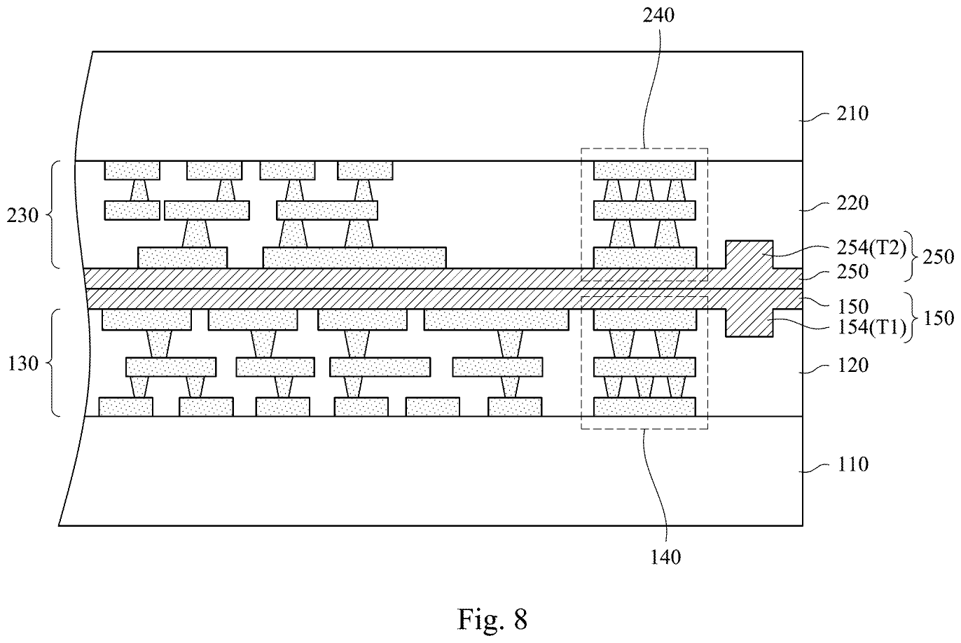

Please refer to FIG. 8, the second component 200 shown in FIG. 7 is flipped upside down to directly bond to the first component 100 shown in FIG. 3. As shown in FIG. 8, the first bonding layer 150 of the first component 100 is in contact with the second bonding layer 250 of the second component 200. In some embodiments, the first seal ring 140 is aligned with the second seal ring 240. The first seal ring 140 and the second seal ring 240 may collectively protect the first component 100 and the second component 200 from crack. In some embodiment, the first trench T1 is aligned with the second trench T2. An interface between the first component 100 and the second component 200 may be a substantially flat surface.

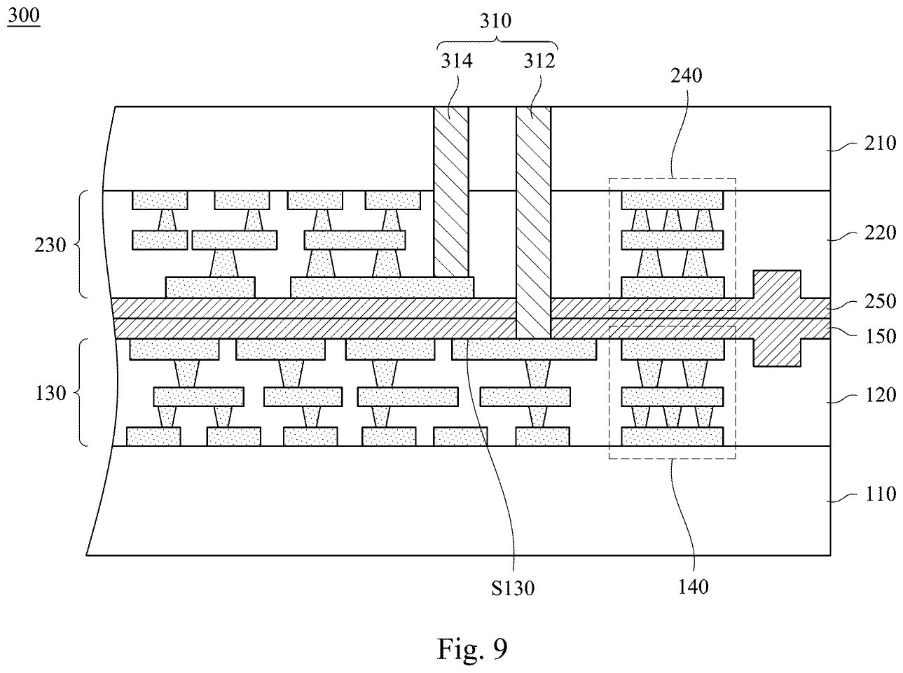

Please refer to FIG. 9, the semiconductor structure 300 is formed. The semiconductor structure 300 includes a first component 100 and a second component 200 bonded to the first component 100. It is understood that the material of the components described above will not be repeated hereinafter.

The first component 100 includes a first interlayer dielectric layer 120, a first interconnect structure 130, a first seal ring 140, a first trench T1, and a first bonding layer 150. The first interconnect structure 130 is in the first interlayer dielectric layer 120, wherein the first interconnect structure 130 has a first surface S130 exposed by the first interlayer dielectric layer 120. The first seal ring 140 surrounds the first interconnect structure 130. The first trench T1 is in the first interlayer dielectric layer 120 and surrounds the first seal ring 140. The first bonding layer 150 covers the first interlayer dielectric layer 120 and the first surface S130 of the first interconnect structure 130.

The second component 200 includes a second interlayer dielectric layer 220, a second interconnect structure 230, a second seal ring 240, a second trench T2, and a second bonding layer 250. The second interconnect structure 230 is in the second interlayer dielectric layer 220, wherein the second interconnect structurer 230 has a second surface S230 exposed by the second interlayer dielectric layer 220. The second seal ring 240 surrounds the second interconnect structurer 230. The second trench T2 in the second interlayer dielectric layer 220 and surrounding the second seal ring 240. The second bonding layer 250 covers the second interlayer dielectric layer 220 and the second surface S230 of the second interconnect structurer 230, wherein the second bonding layer 250 is in contact with the first bonding layer 150.

As shown in FIG. 9, the semiconductor structure 300 may further include conductor 310 electrically connecting the active device (not shown) and the first interconnect structure 130 and/or the second interconnect structure 230. In some embodiments, the conductor 310 includes conductive materials. The conductor 310 may include through silicon via (TSV), but is not limited thereto. In some embodiments, the conductor 310 may include a first conductor 312 and a second conductor 314. The first conductor 312 may penetrate the second interlayer dielectric layer 220, the second bonding layer 250, and the first bonding layer 150 to connect to the first interconnect structure 130. The second conductor 314 penetrates the second interlayer dielectric layer 220 to connect to the second interconnect structurer 230. Specifically, the first conductor 312 and/or the second conductor 314 may be respectively electrically connected to the active device of the second substrate 210, or other wiring structures (not shown).

As described above, according to the embodiments of the present disclosure, a semiconductor structure is provided. In the semiconductor structure of the present disclosure, the first component is directly bonded to the second component. The first component and the second component respectively have a bonding layer in contact with each other. The bonding layers respectively include a plane portion and a guard ring portion. The guard ring portion is disposed in an interlayer dielectric layer and surrounds a seal ring disposed in the interlayer dielectric layer. The plane portion is on the guard ring portion. The guard ring portion of the bonding layers and the seal rings can collectively protect the first component and the second component from crack or delamination during the bonding process.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A semiconductor structure, comprising:
a first component comprising:
a first interlayer dielectric layer;
a first interconnect structure in the first interlayer dielectric layer, wherein the first interconnect structure has a first surface exposed by the first interlayer dielectric layer;
a first seal ring surrounding the first interconnect structure;
a first trench in the first interlayer dielectric layer and surrounding the first seal ring; and
a first bonding layer covering the first interlayer dielectric layer and the first surface of the first interconnect structure; and
a second component bonded to the first component, comprising:
a second interlayer dielectric layer;
a second interconnect structure in the second interlayer dielectric layer, wherein the second interconnect structure has a second surface exposed by the second interlayer dielectric layer;
a second seal ring surrounding the second interconnect structure;
a second trench in the second interlayer dielectric layer and surrounding the second seal ring; and
a second bonding layer covering the second interlayer dielectric layer and the second surface of the second interconnect structure, wherein the second bonding layer is in contact with the first bonding layer.

2. The semiconductor structure of claim 1, wherein the first trench and the second trench are respectively recessed from a top surface of the first interlayer dielectric layer and a bottom surface of the second interlayer dielectric layer, wherein the top surface is level with the first surface of the first interconnect structure, and the bottom surface is level with the second surface of the second interconnect structure.

3. The semiconductor structure of claim 1, wherein the first trench and the second trench respectively have a shape independently selected from a group consisting of a circular shape, a square shape, and a polygon shape viewed from top.

4. The semiconductor structure of claim 1, wherein the first trench is aligned with the second trench.

5. The semiconductor structure of claim 1, further comprising:
a third trench in the first interlayer dielectric layer and between the first seal ring and the first interconnect structure, wherein the first bonding layer extends into the third trench; and
a fourth trench in the second interlayer dielectric layer and between the second seal ring and the second interconnect structure, wherein the second bonding layer extends into the fourth trench.

6. The semiconductor structure of claim 1, wherein the first bonding layer comprises a first guard ring portion in the first trench and a first plane portion on the first guard ring portion, and the second bonding layer comprises a second guard ring portion in the second trench and a second plane portion under the second guard ring portion.

7. The semiconductor structure of claim 6, wherein the first guard ring portion and the second guard ring portion respectively comprise a plurality of separate segments around the first seal ring and the second seal ring.

8. The semiconductor structure of claim 1, wherein the first bonding layer and the second bonding layer comprises organic material.

9. The semiconductor structure of claim 1, further comprising:
a first conductor penetrating the second interlayer dielectric layer, the second bonding layer, and the first bonding layer to connect to the first interconnect structure; and
a second conductor penetrating the second interlayer dielectric layer to connect to the second interconnect structure.

10. The semiconductor structure of claim 1, further comprising a first substrate under the first interlayer dielectric layer and a second substrate on the second interlayer dielectric layer.
